(19) United States
(12) Patent Application Publication
(10) Pub. No.: US 2017/0093413 A1
(43) Pub. Date: Mar. 30, 2017

(54) SIGNAL PROCESSING APPARATUS FOR MEASURING MACHINE

(71) Applicant: MITUTOYO CORPORATION, Kawasaki (JP)

(72) Inventor: Toshihiro KANEMATSU, Miyazaki-shi (JP)

(73) Assignee: MITUTOYO CORPORATION, Kawasaki (JP)

(21) Appl. No.: 15/274,955

(22) Filed: Sep. 23, 2016

(30) Foreign Application Priority Data
Sep. 29, 2015 (JP) 2015-190868

(51) Int. Cl. H03M 1/00

(52) U.S. Cl. CPC H03M 1/001

(57) ABSTRACT

There is provided a signal processing apparatus, which can perform measurement with a wide dynamic range and high resolution, for a measuring machine. A first analog-to-digital (AD) converter AD-converts a sensor signal into an upper digital signal. A first digital-to-analog (DA) converter DA-converts the upper digital signal into an upper analog signal. A first combining unit generates a lower analog signal by subtracting the upper analog signal from the sensor signal. An amplifier generates a magnified lower analog signal by amplifying the lower analog signal. A second AD converter AD-converts the magnified lower analog signal into a lower digital signal. A second combining unit combines the upper digital signal regarded as upper side digits with the lower digital signal regarded as lower side digits.

### INCORPORATION BY REFERENCE

This application is based upon and claims the benefit of priority from Japanese patent application No. 2015-190868, filed on Sep. 29, 2015, the disclosure of which are incorporated herein in its entirety by reference.

### BACKGROUND OF THE INVENTION

1. Field of the Invention

The present invention relates to a signal processing apparatus for a measuring machine.

2. Description of Related Art

Measuring machines are required to detect an output signal of a sensor with high-resolution.

Here, the resolution is determined based on an amplification factor of a preamplifier and the number of bits of an analog-to-digital (AD) converter. On the other hand, if the sensor output varies over a wide range, the dynamic range needs to be enlarged.

The dynamic range is also determined based on the amplification factor of the preamplifier and the number of bits of the AD converter. The resolution and the dynamic range have a trade-off relation; the dynamic range becomes narrower as the resolution becomes higher.

Conventionally, the gain (amplification factor) of the preamplifier has been switched according to the range. For example, in the signal processing apparatus for the measuring machine disclosed in JP 2002-162251 A, a user can gradually switch the range as needed. The CPU automatically adjusts the gain according to the range selected by the user.

### SUMMARY OF THE INVENTION

However, as long as the number of bits of an AD converter is fixed, resolution and a dynamic range keeps a trade-off relation, and it is difficult to perform measurement with a wide dynamic range and high resolution.

A purpose of the present invention is to provide a signal processing apparatus, which can perform measurement with a wide dynamic range and high resolution, for a measuring machine.

A signal processing apparatus for a measuring machine in an aspect of the present invention is the signal processing apparatus, which converts an analog sensor signal corresponding to a measurement value into a digital signal to be used as measurement data, for the measuring machine, the apparatus including:

a first analog-to-digital (AD) converter configured to AD-convert the sensor signal into an upper digital signal;

a first digital-to-analog (DA) converter configured to DA-convert the upper digital signal into an upper analog signal;

a first combining unit configured to generate a lower analog signal by subtracting the upper analog signal from the sensor signal;

an amplifier configured to generate a magnified lower analog signal by magnifying the lower analog signal;

a second AD converter configured to AD-convert the magnified lower analog signal into a lower digital signal; and

a second combining unit configured to combine the upper digital signal regarded as upper side digits with the lower digital signal regarded as lower side digits.

In an aspect of the present invention, resolution of the first DA converter may be set to be equal to or lower than resolution of the first AD converter.

In an aspect of the present invention, the resolution of the first AD converter may be set to be equal to the resolution of the first DA converter.

A measuring machine in an aspect of the present invention includes the signal processing apparatus for the measuring machine and a sensor.

### BRIEF DESCRIPTION OF THE DRAWINGS

FIG. 1 is a functional block diagram of a signal processing apparatus according to a first exemplary embodiment;

FIG. 2 is a diagram illustrating an example of a sensor signal E1;

FIG. 3 is a diagram illustrating an example of a result obtained by AD-converting the sensor signal E1;

FIG. 4 is a diagram illustrating an example of an upper analog signal E3;

FIG. 5 is a diagram illustrating an example of an inverted upper analog signal E4;

FIG. 6 is a diagram illustrating an example of a lower analog signal E5;

FIG. 7 is a diagram illustrating an example of a magnified lower analog signal E6;

FIG. 8 is a diagram illustrating an example of a lower digital signal E7;

FIG. 9 is a diagram illustrating an example of a combined digital signal E8; and

FIG. 10 is a diagram illustrating a configuration example of a circuit as an example 1.

### DETAILED DESCRIPTION

An embodiment of the present invention is illustrated and described with reference to the reference signs attached to the elements in the drawings.

### First Exemplary Embodiment

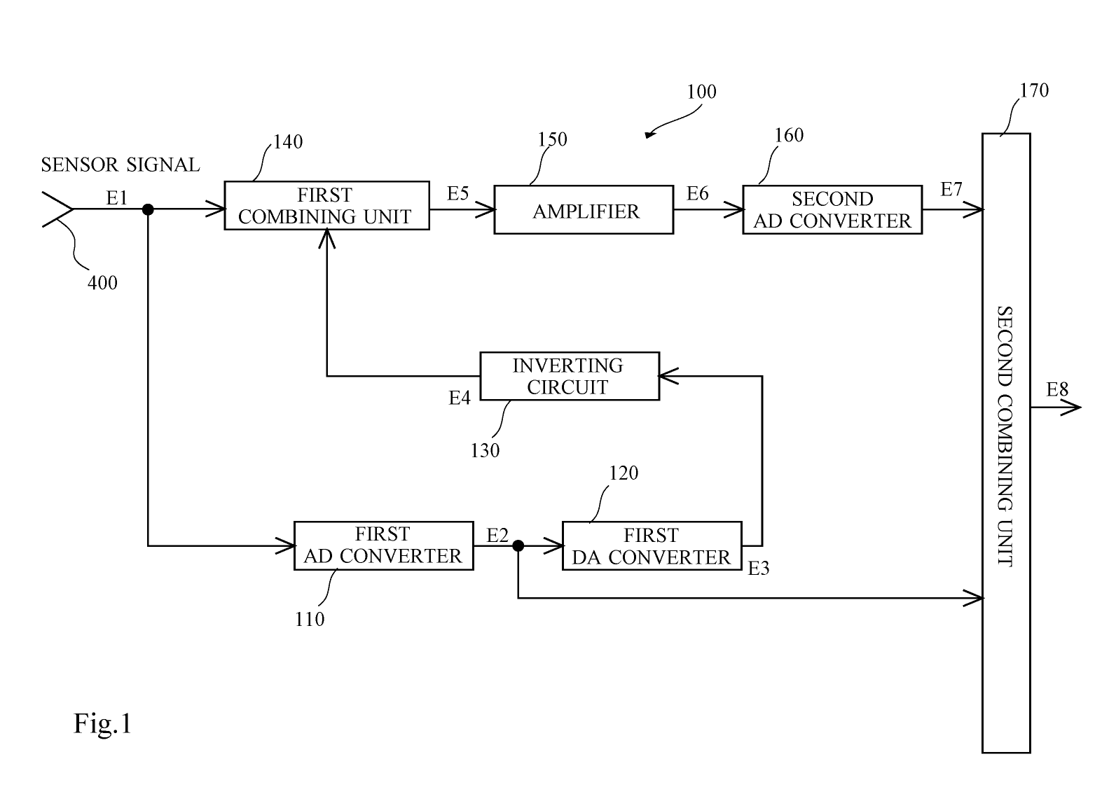

FIG. 1 is a functional block diagram of a signal processing apparatus 100 according to a first exemplary embodiment of the present invention.

Processing performed by each functional unit is described along the path of a signal in order.

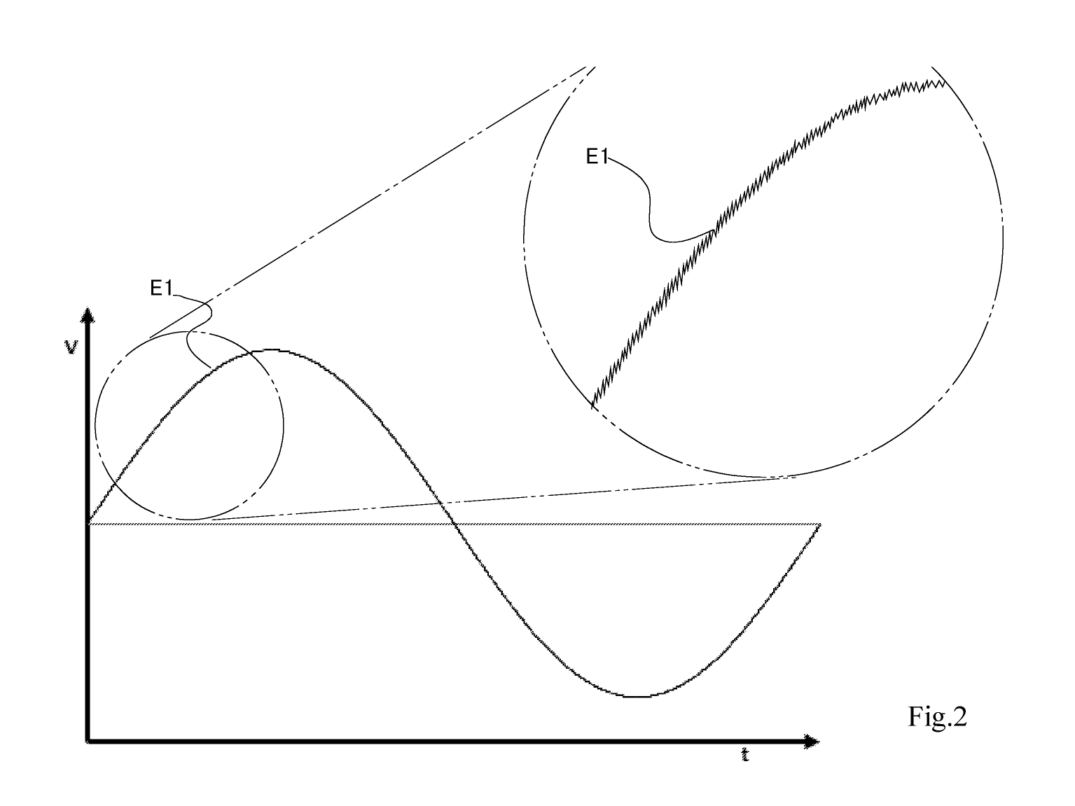

First, a sensor signal E1 is input from a sensor circuit 400 to the signal processing apparatus 100. An example of the sensor signal E1 is illustrated in FIG. 2. The sensor circuit 400 is a differential inductance which detects, for example, displacement of a stylus of a shape measuring machine, and outputs an analog signal which varies according to the displacement of the stylus.

For example, the sensor signal E1 is composed of a signal of waviness and fine-unevenness superimposed on an outline as a whole as illustrated in FIG. 2.

The sensor signal E1 is branched into two; one is input to a first analog-to-digital (AD) converter 110, and the other is input to a first combining unit 140.

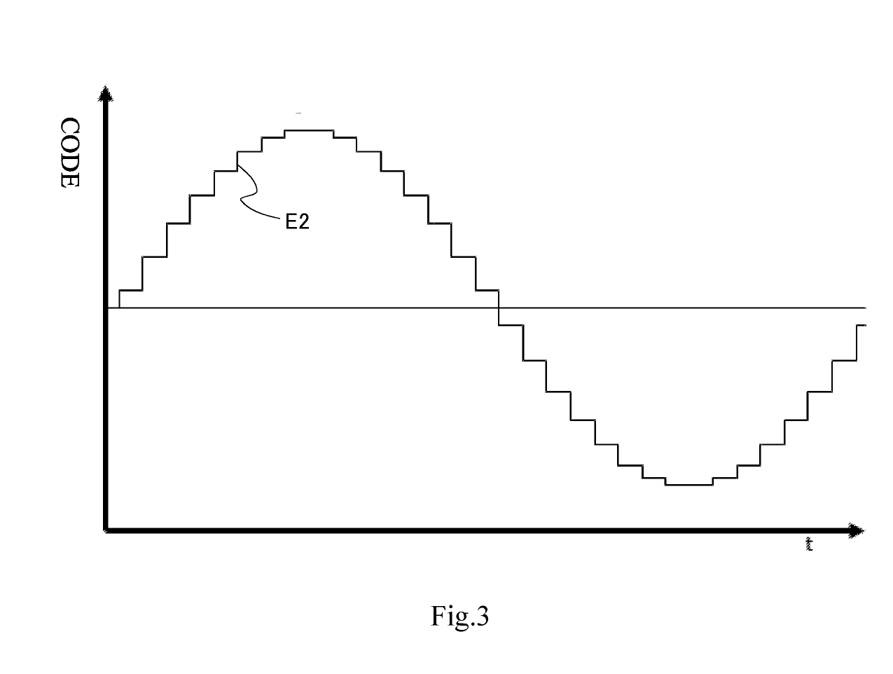

The sensor signal E1 is converted into a digital signal by the first AD converter 110. An example of the result of the AD-converted sensor signal E1 is illustrated in FIG. 3.

The signal converted into the digital signal by the first AD converter 110 is referred to as an upper digital signal E2.

As illustrated in FIG. 3, in order to enlarge the range of the first AD converter 110, the first AD converter 110 relatively coarsely performs the digital conversion.

The upper digital signal E2 is branched into two; one is input to a second combining unit 170, and the other is input to a first digital-to-analog (DA) converter 120.

The upper digital signal E2 is converted into an analog signal again by the first DA converter 120. The signal converted into the analog signal by the first DA converter 120 is referred to as an upper analog signal E3.

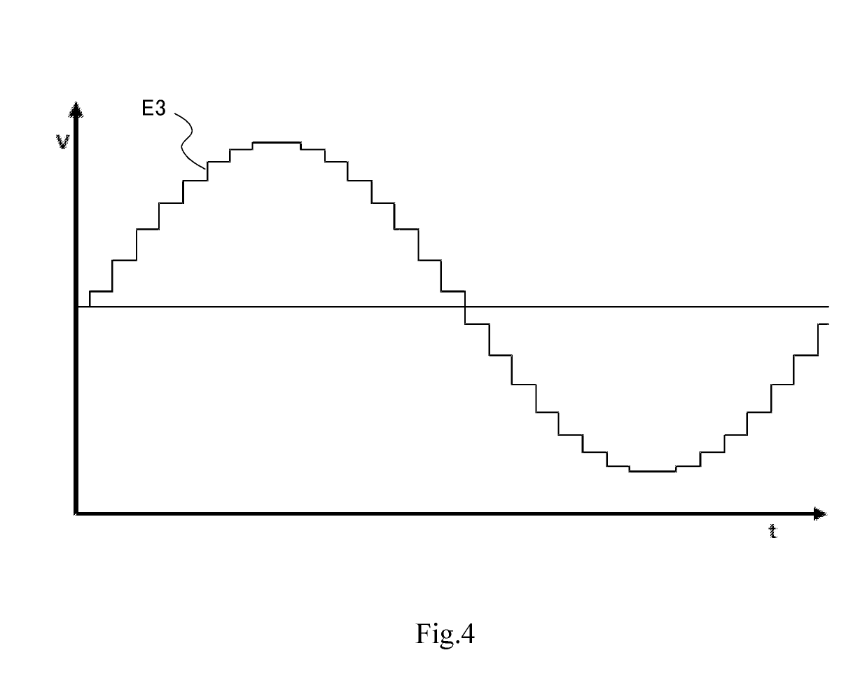

An example of the upper analog signal E3 is illustrated in FIG. 4.

The upper analog signal E3 is obtained by removing the variation below the resolution of the first AD converter 110 from the sensor signal E1.

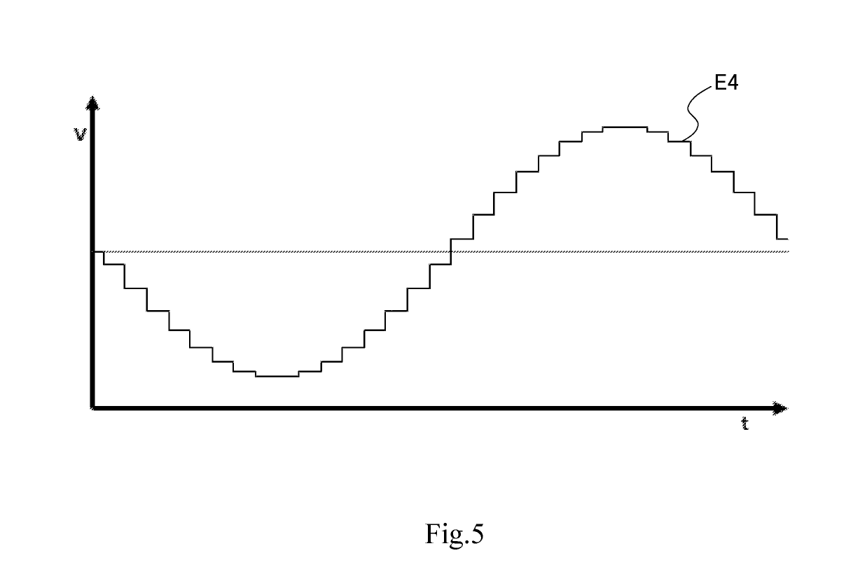

The upper analog signal E3 is input to the first combining unit 140 after an inverting circuit 130 performs inversion processing. The signal inverted by the inverting circuit 130 is referred to as an inverted upper analog signal E4, and an example thereof is illustrated in FIG. 5.

To the first combining unit 140, the sensor signal E1 is input from the one input end, and the inverted upper analog signal E4 is input from the other input end.

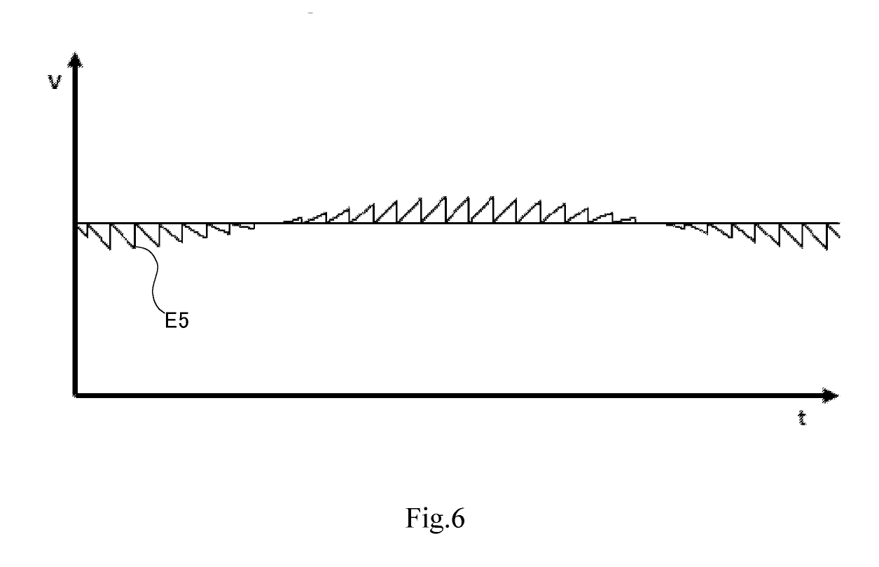

The first combining unit 140 combines the sensor signal E1 with the inverted upper analog signal E4. The signal obtained by combining the sensor signal E1 with the inverted upper analog signal E4 is referred to as a lower analog signal E5, and an example thereof is illustrated in FIG. 6.

The lower analog signal E5 is obtained by extracting the variation below the resolution of the first AD converter 110 from the sensor signal E1.

The lower analog signal E5 is amplified by an amplifier 150, and the amplified signal is referred to as a magnified lower analog signal E6.

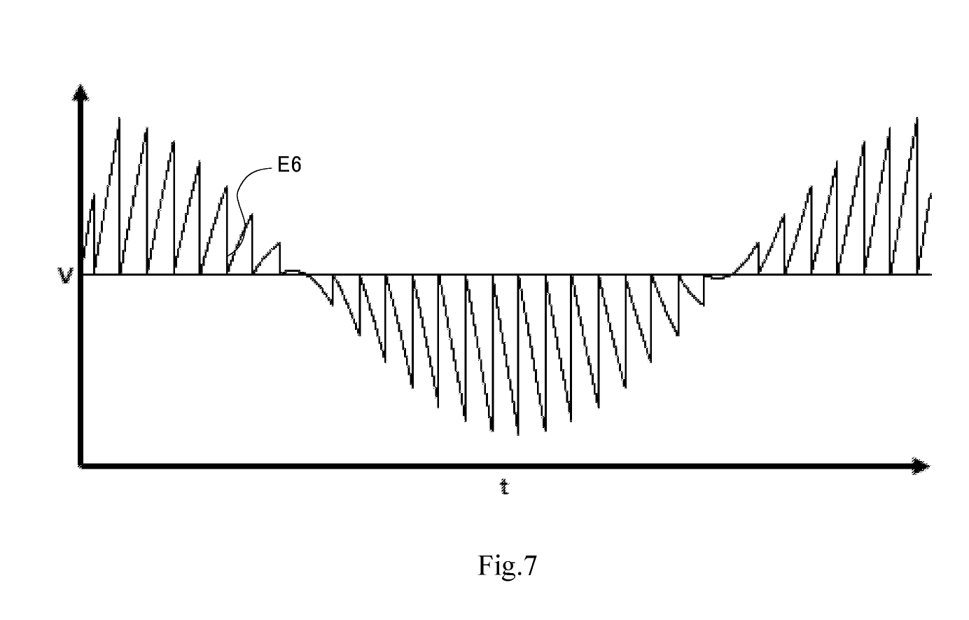

An example of the magnified lower analog signal E6 is illustrated in FIG. 7. Then, the magnified lower analog signal E6 is converted into a digital signal by a second AD converter 160.

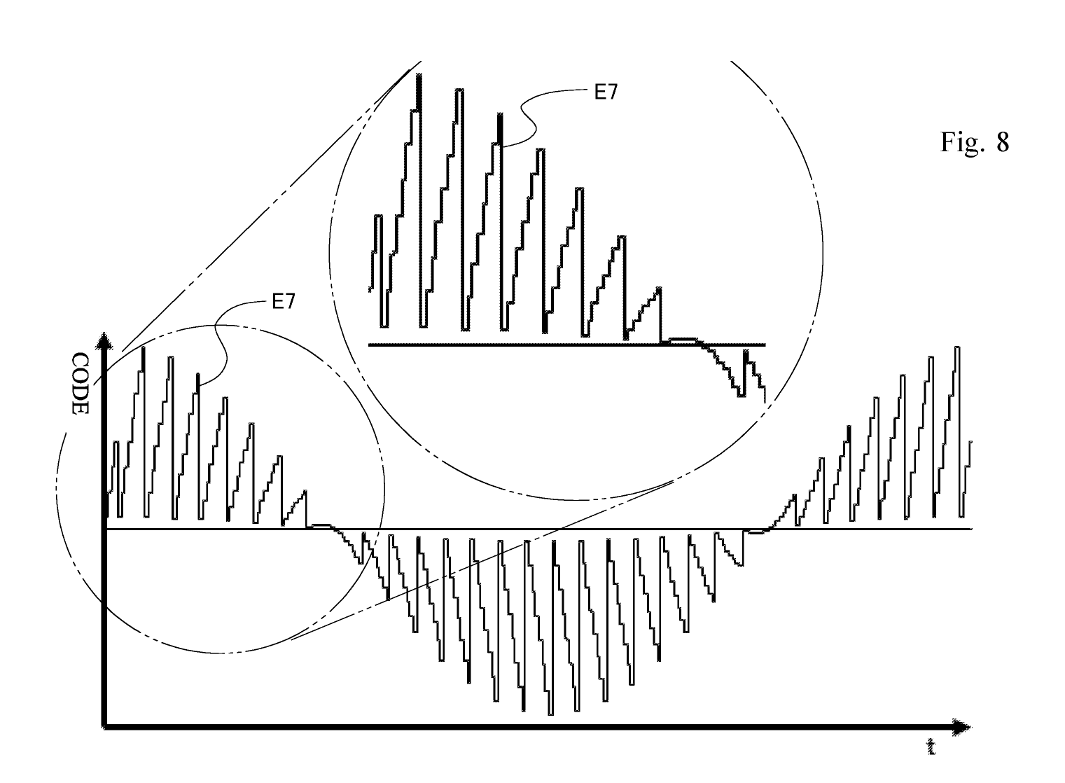

The signal converted into the digital signal by the second AD converter 160 is referred to as a lower digital signal E7, and an example thereof is illustrated in FIG. 8. The lower digital signal E7 is obtained by magnifying and then AD converting the lower analog signal E5, that is, by extracting, as digital data, the variation below the resolution of the first AD converter 110 from the sensor signal E1.

The lower digital signal E7 is input to the second combining unit 170.

To the second combining unit 170, the upper digital signal E2 is input from the one input end, and the lower digital signal E7 is input from the other input end.

The second combining unit 170 combines the upper digital signal E2 with the lower digital signal E7.

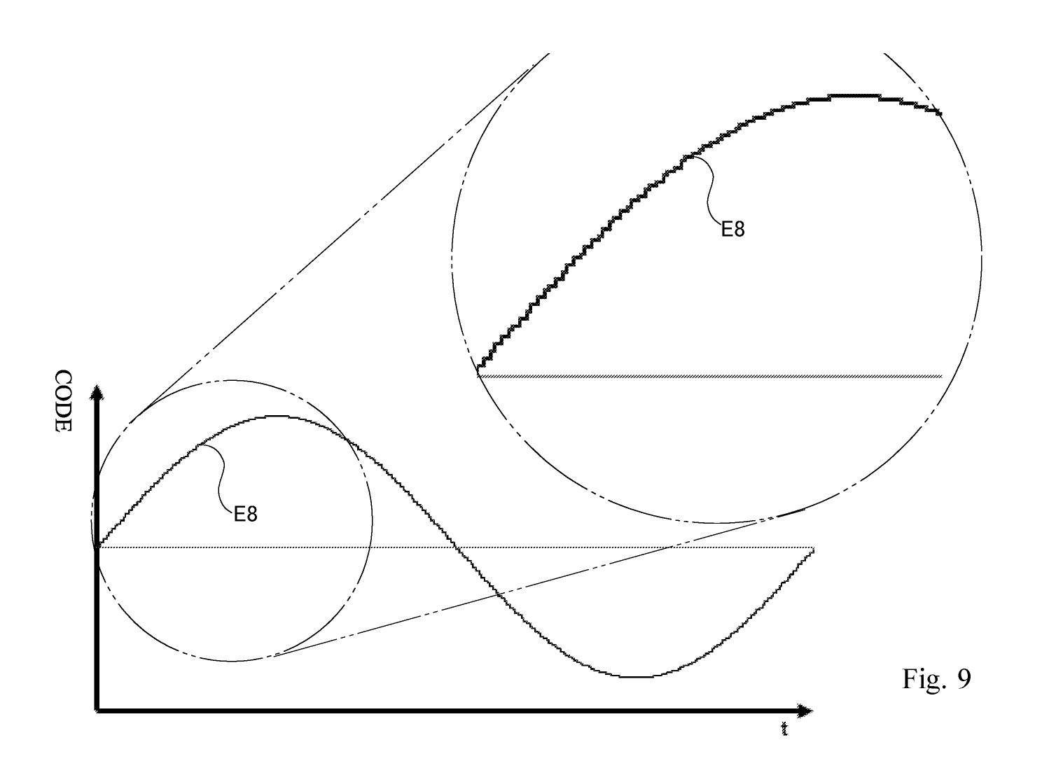

At this time, the upper digital signal E2 is regarded as upper side bits, and the lower digital signal E7 is regarded as lower side bits. Then, a combined digital signal E8 illustrated in FIG. 9 is obtained.

The combined digital signal E8 obtained in this manner is measurement data having a wide dynamic range as well as high resolution.

### EXAMPLE 1

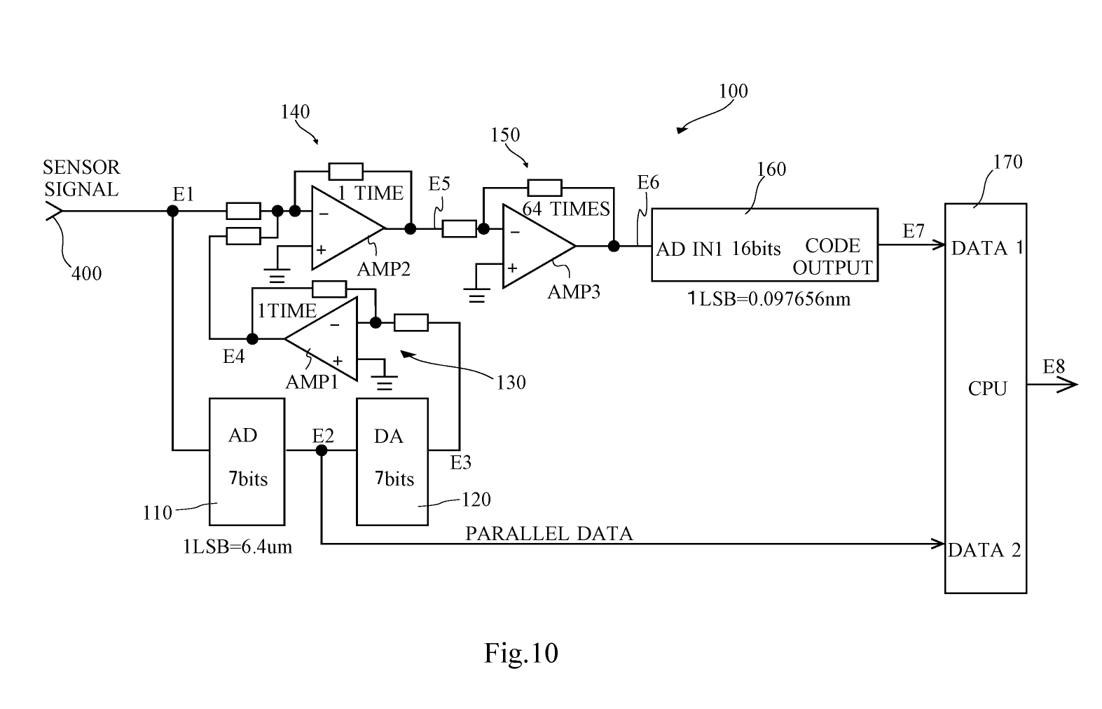

FIG. 10 illustrates a configuration example of a circuit as an example 1.

In FIG. 10, the inverting circuit 130, the first combining unit 140, and the amplifier 150 are implemented by operational amplifiers AMP1 to AMP3 respectively. Note that, the first combining unit 140 is an inverting adder circuit, and the amplifier 150 is an inverting amplifier circuit.

Furthermore, as an example, circuit conditions are set as follows:

The measurement range of the sensor is 819.2 um, and the sensor signal E1 is an electric signal having the amplitude of 10 V.

The first AD converter 110 and the first DA converter 120 have the input range of 10 V and the resolution of 7 bits.

Note that, the resolution of the first AD converter 110 is set to be equal to that of the first DA converter 120.

The gains of the operational amplifiers AMP1 and AMP2 which constitute the inverting circuit 130 and the first combining unit 140 respectively are one time, and the gain of the operational amplifier AMP3 constituting the amplifier 150 is 64 times.

The second AD converter 160 has the input range of 10 V and the resolution of 16 bits.

At this time, in the lowest bit (LSB) of the first AD converter 110 and the first DA converter 120, the amplitude level is 78.125 mV and the resolution is equivalent to 6.4 μm.

Here, the second AD converter 160 is described.

The bits below the lowest bit (LSB) (6.4 μm) of the first AD converter 110 and the first DA converter 120 are magnified to the amplitude of 10 V (that is, 128 times), and is expressed with 16 bits.

Thus, the lowest bit (LSB) of the second AD converter 160 is equivalent to 0.000097656 um.

In other words, that the second combining unit 170 combines the upper digital signal with the lower digital signal means that digital conversion can be performed with high resolution equivalent to 23 bits.

819.2 um/0.000097656 um=8388629=(equivalent to) 23 bits

Note that, in order for the first combining unit 140 to combine the sensor signal E1 with the inverted upper analog signal E4, it is necessary that the delay of the inverted upper analog signal E4 to the sensor signal E1 is taken into consideration.

When it is assumed that the sensor signal E1 is a sine wave, the inverted upper analog signal E4 needs to be generated in a half period of the sensor signal E1.

It is assumed that the total delay of the first AD converter 110, the first DA converter 120, and the inverting circuit 130 is td, and the number of bits of the first AD converter 110 (the first DA converter 120) is n.

Furthermore, it is assumed that he shortest period of the sensor signal E1 is Tmin, and the maximum frequency is Fmax.

At this time, T min/2=td×2ⁿ is established, and thus Fmax=1/(2×td×2ⁿ) is established.

Note that, the present invention is not limited to the above embodiment, and can be appropriately changed without deviating from the scope.

In the above example, the inverting circuit 130 is interposed, but if, for example, the first DA converter 120 performs output inversely, the inverting circuit 130 is not necessary.

Alternately, as long as the first combining unit 140 functions as a subtracting device, the inverting circuit 130 may be omitted.

In the embodiment, it has been exemplified that the resolution of the first AD converter 110 is to be equal to that of the first DA converter 120, but the resolution of the first AD converter 110 may be different from that of the first DA converter 120, and, for example, the resolution of the first DA converter 120 may be lower than that of the first AD converter 110.

It is needless to say that the kind of sensor is not limited.

1. A signal processing apparatus, which converts an analog sensor signal corresponding to a measurement value into a digital signal to be used as measurement data, for a measuring machine, the apparatus comprising:
a first analog-to-digital (AD) converter configured to AD-convert the sensor signal into an upper digital signal;
a first digital-to-analog (DA) converter configured to DA-convert the upper digital signal into an upper analog signal;
a first combining unit configured to generate a lower analog signal by subtracting the upper analog signal from the sensor signal; an amplifier configured to generate a magnified lower analog signal by magnifying the lower analog signal;
a second AD converter configured to AD-convert the magnified lower analog signal into a lower digital signal; and
a second combining unit configured to combine the upper digital signal regarded as upper side digits with the lower digital signal regarded as lower side digits.

2. The signal processing apparatus for the measuring machine according to claim 1, wherein resolution of the first DA converter is set to be equal to or lower than resolution of the first AD converter.

3. The signal processing apparatus for the measuring machine according to claim 2, wherein the resolution of the first AD converter is set to be equal to the resolution of the first DA converter.

4. A measuring machine comprising:
the signal processing apparatus for the measuring machine according to claim 1; and
a sensor.
